(19) United States
(12) Patent Application Publication
(10) Pub. No.: US 2025/0132176 A1
(43) Pub. Date: Apr. 24, 2025

(54) HEATERS, AND RELATED CHAMBER KITS AND PROCESSING CHAMBERS, FOR SEMICONDUCTOR MANUFACTURING

(71) Applicant: Applied Materials, Inc., Santa Clara, CA (US)

(72) Inventors: Enle CHOO, Saratoga, CA (US); Shu-Kwan LAU, Sunnyvale, CA (US); Amir H. TAVAKOLI, San Jose, CA (US)

(21) Appl. No.: 18/912,896

(22) Filed: Oct. 11, 2024

Related U.S. Application Data
(60) Provisional application No. 63/545,008, filed on Oct. 20, 2023.

(51) Int. Cl. H01L 21/67; H05B 3/62

(52) U.S. Cl. CPC H01L 21/67115; H05B 3/62

(57) ABSTRACT

The present disclosure relates to heaters, and related chamber kits and processing chambers, for semiconductor manufacturing. In one or more embodiments, a chamber kit applicable for semiconductor manufacturing includes a heater and a liner. The heater includes an arcuate heater body including one or more first sections, one or more second sections, and one or more connector sections. The heater includes a first electrode coupled to the arcuate heater body, and a second electrode coupled to the arcuate heater body. The liner includes a ledge sized and shaped to support the arcuate heater body, a first opening sized and shaped to receive at least part of the heater therethrough, and a second opening sized and shaped to receive at least part of the heater therethrough.

### CROSS-REFERENCE TO RELATED APPLICATION

This application claims the benefit of U.S. provisional patent application Ser. No. 63/545,008, filed Oct. 20, 2023, which is herein incorporated by reference in its entirety.

### BACKGROUND

### Field

The present disclosure relates to heaters, and related chamber kits and processing chambers, for semiconductor manufacturing.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities, which can involve hindered device performance and/or reduced throughput. For example, activation of gases can be limited and/or can involve non-uniform activation, which can cause limited and/or non-uniform film growth and/or dopant concentration.

Therefore, a need exists for improved apparatuses and methods in semiconductor processing.

### SUMMARY

The present disclosure relates to heaters, and related chamber kits and processing chambers, for semiconductor manufacturing.

In one or more embodiments, a chamber kit applicable for semiconductor manufacturing includes a heater and a liner. The heater includes a heater body including one or more first sections, one or more second sections, and one or more connector sections. The heater includes a first electrode coupled to the heater body, and a second electrode coupled to the heater body. The liner includes a ledge sized and shaped to support the heater body, a first opening sized and shaped to receive at least part of the heater therethrough, and a second opening sized and shaped to receive at least part of the heater therethrough.

In one or more embodiments, a chamber kit applicable for semiconductor manufacturing includes a heater and a liner. The heater includes a heater body including a first ring segment, a second ring segment spaced from the first ring segment, and a connector section between the first ring segment and the second ring segment. The heater includes a first electrode coupled to the heater body, and a second electrode coupled to the heater body. The chamber kit includes a liner including a ledge sized and shaped to support the heater body.

In one or more embodiments, a processing chamber applicable for use in semiconductor manufacturing includes a chamber body including an inject side and an exhaust side. The processing chamber includes a substrate support disposed in a processing volume, and a heater disposed adjacent the inject side of the chamber body. The heater includes an arcuate heater body that includes one or more first sections, one or more second sections, and one or more connector sections. The heater includes a first electrode coupled to the arcuate heater body and extending at least partially through the chamber body, and a second electrode coupled to the arcuate heater body and extending at least partially through the chamber body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one or more embodiments.

FIG. 2 is a schematic partial top cross-sectional view of the processing chamber shown in FIG. 1, according to one or more embodiments.

FIG. 3 is a schematic perspective view of the first heater shown in FIGS. 1 and 2, according to one or more embodiments.

FIG. 4 is a schematic front view of the first heater shown in FIG. 3, according to one or more embodiments.

FIG. 5 is a schematic partial top view of a first heater of the one or more heaters shown in FIG. 1, according to one or more embodiments.

FIG. 6 is a schematic front view of the first heater shown in FIG. 5, according to one or more embodiments.

FIG. 7 is a schematic partial top view of a first heater and a second heater, according to one or more embodiments.

FIG. 8 is a schematic front view of the first heater and the second heater shown in FIG. 7, according to one or more embodiments.

FIG. 9 is a schematic partial top view of a first heater and a second heater, according to one or more embodiments.

FIG. 10 is a schematic partial top view of a first heater and a second heater, according to one or more embodiments.

FIG. 11 is a schematic front view of the first heater shown in FIG. 10, according to one or more embodiments.

FIG. 12 is a schematic partial top view of a first heater, according to one or more embodiments.

FIG. 13 is a schematic partial cross-sectional side view of the first heater shown in FIG. 3 disposed in the processing chamber in FIG. 1, according to one or more embodiments.

FIG. 14 is a schematic partial cross-sectional side view of the first heater shown in FIG. 3 disposed in the processing chamber in FIG. 1, according to one or more embodiments.

FIG. 15 is a schematic partial cross-sectional side view of the first heater shown in FIG. 3 disposed in the processing chamber in FIG. 1, according to one or more embodiments.

FIG. 16 is a schematic block diagram view of a method of substrate processing for semiconductor manufacturing, according to one or more embodiments.

FIG. 17 is a schematic perspective view of a heater, according to one or more embodiments.

FIG. 18 is a schematic front view of the heater shown in FIG. 17, according to one or more embodiments.

FIG. 19 is a schematic top view of the heater shown in FIGS. 17 and 18, according to one or more embodiments.

FIG. 20 is a schematic perspective top of a heater, according to one or more embodiments.

FIG. 21 is a schematic perspective top of a heater, according to one or more embodiments.

FIG. 22 is a schematic partial cross-sectional side view of the first heater shown in FIG. 3 disposed in the processing chamber in FIG. 1, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to heaters, and related chamber kits and processing chambers, for semiconductor manufacturing.

The disclosure contemplates that terms such as “couples,” “coupling,” “couple,” and “coupled” may include but are not limited to bonding, embedding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

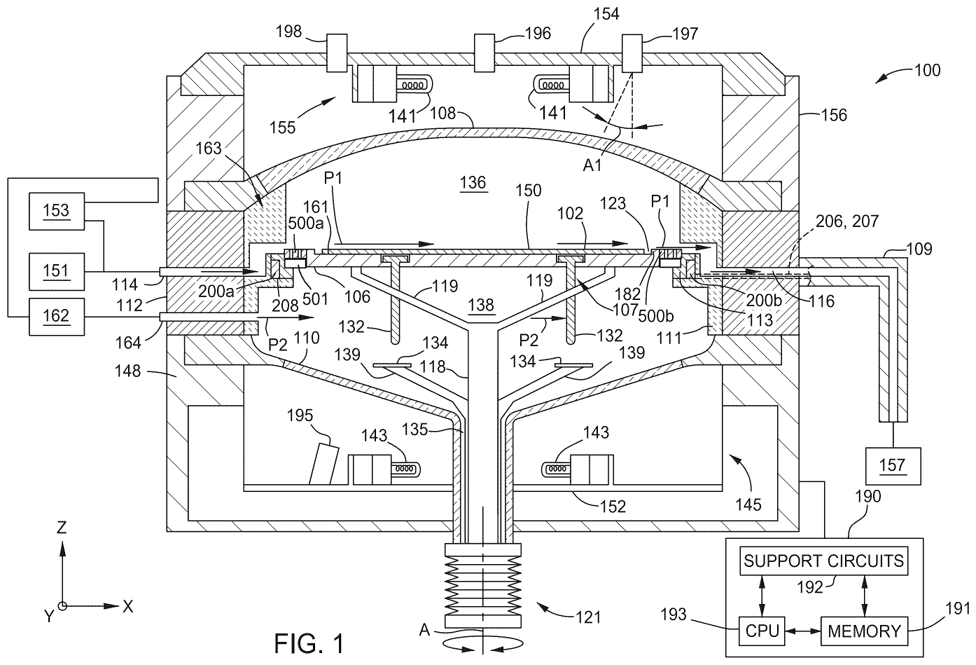

FIG. 1 is a schematic side cross-sectional view of a processing chamber 100, according to one or more embodiments. The processing chamber 100 is a deposition chamber. In one or more embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102. The processing chamber 100 is shown in a processing condition in FIG. 1.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper plate 108 (such as an upper window and/or an upper dome), a lower plate 110 (such as a lower window and/or a lower dome), and one or more heat sources 141, 143. The one or more heat sources 141, 143 include a plurality of upper heat sources 141 and a plurality of lower heat sources 143. In one or more embodiments, the upper heat sources 141 include upper lamps and the lower heat sources 143 include lower lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper plate 108 and the lower plate 110. The substrate support 106 supports the substrate 102. In one or more embodiments, the substrate support 106 includes a susceptor. Other substrate supports (including, for example, a substrate carrier and/or one or more ring segment(s) that support one or more outer regions of the substrate 102) are contemplated by the present disclosure. The plurality of upper heat sources 141 are disposed between the upper plate 108 and a lid 154. The plurality of upper heat sources 141 form a portion of the upper heat source module 155.

The plurality of lower heat sources 143 are disposed between the lower plate 110 and a floor 152. The plurality of lower heat sources 143 form a portion of a lower heat source module 145. The upper plate 108 is formed of an energy transmissive material, such as quartz. The lower plate 110 is formed of an energy transmissive material, such as quartz.

A processing volume 136 and a purge volume 138 are formed between the upper plate 108 and the lower plate 110. The processing volume 136 and the purge volume 138 are part of an internal volume defined at least partially by the upper plate 108, the lower plate 110, and one or more liners 111, 163. In one or more embodiments, the processing volume 136 is a processing volume. The one or more liners 111, 163 are disposed inwardly of the chamber body.

The internal volume has the substrate support 106 disposed therein. The substrate support 106 includes a top surface on which the substrate 102 is disposed. The substrate support 106 is attached to a shaft 118. In one or more embodiments, the substrate support 106 is connected to the shaft 118 through one or more arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are each sized to accommodate a lift pin 132 for lifting of the substrate 102 from the substrate support 106 before or after a deposition process is performed. The lift pins 132 may rest on lift pin stops 134 when the substrate support 106 is lowered from a process position to a transfer position. The lift pin stops 134 can include a plurality of arms 139 that attach to a shaft 135.

The flow module 112 includes one or more gas inlets 114 (e.g., a plurality of gas inlets), one or more purge gas inlets 164 (e.g., a plurality of purge gas inlets), and one or more gas exhaust outlets 116. The one or more gas inlets 114 and the one or more purge gas inlets 164 are disposed on the opposite side of the flow module 112 from the one or more gas exhaust outlets 116. A pre-heat ring 501 is disposed below the one or more gas inlets 114 and the one or more gas exhaust outlets 116. The pre-heat ring 501 is disposed above the one or more purge gas inlets 164. The one or more liners 111, 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a respective one or more process gases P1 and one or more purge gases P2 parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. The one or more process gases P1 supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). The one or more purge gases P2 supplied using the one or more purge gas sources 162 can include one or more inert gases (such as one or more of argon (Ar), helium (He), and/or nitrogen (N₂)). One or more cleaning gases supplied using the one or more cleaning gas sources 153 can include one or more of hydrogen (H) and/or chlorine (Cl). In one or more embodiments, the one or more process gases P1 include silicon phosphide (SiP) and/or phospine (PH₃), and the one or more cleaning gases include hydrochloric acid (HCl).

The one or more gas exhaust outlets 116 are further connected to or include an exhaust system 109. The exhaust system 109 fluidly connects the one or more gas exhaust outlets 116 and the exhaust pump 157. The exhaust system 109 can assist in the controlled deposition of a layer on the substrate 102. The exhaust system 109 is disposed on an opposite side of the processing chamber 100 relative to the flow module 112.

The processing chamber 100 includes the one or more liners 111, 163 (e.g., a lower liner 111 and an upper liner 163). The flow module 112 (which can be at least part of a sidewall of the processing chamber 100) includes the one or more gas inlets 114 in fluid communication with the processing volume 136. The one or more gas inlets 114 are in fluid communication with one or more flow gaps between the upper liner 163 and a lower liner 111. The one or more second gas inlets 175 are in fluid communication with the one or more inlet openings 183 of the upper liner 163.

During a deposition operation (e.g., an epitaxial growth operation), the one or more process gases P1 flow through the one or more gas inlets 114, through the one or more gaps, and into the processing volume 136 to flow over the substrate 102.

The present disclosure also contemplates that the one or more purge gases P2 can be supplied to the purge volume 138 (through the one or more purge gas inlets 164) during the deposition operation, and exhausted from the purge volume 138. The one or more purge gases P2 flow simultaneously with the flowing of the one or more process gases P1. The one or more process gases P1 are exhausted through gaps between the upper liner 163 and the lower liner 111, and through the one or more gas exhaust outlets 116. The one or more purge gases P2 can be exhausted through one or more outlet openings, and through the same one or more gas exhaust outlets 116 as the one or more process gases P1. The present disclosure contemplates that that the one or more purge gases P2 can be separately exhausted through one or more second gas exhaust outlets that are separate from the one or more gas exhaust outlets 116.

During a cleaning operation, one or more cleaning gases flow through the one or more gas inlets 114, through the one or more gaps (between the upper liner 163 and the lower liner 111), and into the processing volume 136.

One or more heaters 500a, 500b can be controlled to heat the one or more process gases P1 (and/or the cleaning gases) to facilitate breaking bonds for deposition on the substrate 102. As an example, the one or more heaters 500a, 500b can heat the one or more process gases P1 before and after flowing over the substrate 102. As another example, the one or more heaters 500a, 500b can heat the one or more process gases P1 at area(s) adjacent to an outer annular region of the substrate 102. In one or more embodiments, the one or more heaters 500a, 500b include a plurality of heaters 500a, 500b (two are shown in FIG. 1) disposed on opposing sides of the processing volume 136. The present disclosure contemplates that one or both of the heaters 500a, 500b may be used. In addition to or instead of the one or more heaters 500a, 500b, one or more heaters 200a, 200b are at least partially covered and/or supported by the one or more liners 111, 163. The one or more heaters 200a, 200b can be controlled to heat the one or more process gases P1 (and/or the cleaning gases). In one or more embodiments, the one or more heaters 200a, 200b include a plurality of heaters 200a, 200b (two are shown in FIG. 1) disposed on opposing sides of the processing volume 136. The present disclosure contemplates that one or both of the heaters 200a, 200b may be used. The present disclosure contemplates that the one or more heaters 500a, 500b can be used in place of the pre-heat ring 501, or the one or more heaters 500a, 500b can be used in addition to the pre-heat ring 501. As an example, the one or more heaters 500a, 500b and/other heater(s) can be disposed above or below the pre-heat ring 501. A second lower liner 113 is at least partially supported by the lower liner 111, and the second lower liner 113 at least partially covers and/or supports the one or more heaters 200a, 200b. In one or more embodiments using the lower liner 111 and the second lower liner 113, at least part of all outer sides of each heater 200a, 200b are covered and blocked from the one or more process gases P1 and/or the cleaning gases.

The processing system includes one or more sensor devices 195, 196, 197, 198 (e.g., temperature sensors) configured to measure parameter(s) (e.g., temperature(s)) within the processing chamber 100. In one or more embodiments, the one or more temperature sensor devices 195, 196, 197, 198 include a central sensor device 196 and one or more outer sensor devices 195, 197, 198. A controller 190 (described below) can control the one or more sensor devices 195, 196, 197, 198, and can conduct method(s) analyzing uniformity of substrate processing using at least one of the one or more sensor devices 195, 196, 197, 198. In one or more embodiments, the one or more sensor devices 195, 196, 197, 198 each include a sensor that includes one or more of silicon (Si), carbon (C), gallium (Ga), and/or nitrogen (N). In one or more embodiments, the one or more sensor devices 195, 196, 197, 198 each include a silicon sensor, a silicon carbide (SiC) sensor, and/or a gallium nitride (GaN) sensor. In one or more embodiments, each sensor device 195, 196, 197, 198 is a pyrometer and/or optical sensor, such as an optical pyrometer. The present disclosure contemplates that sensor devices other than pyrometers may be used, and/or one or more of the sensor devices 195, 196, 197, 198 can measure properties (such as metrology properties) other than temperature.

In one or more embodiments, the one or more sensor devices 195, 196, 197, 198 include one or more upper sensor devices 196, 197, 198 disposed above the substrate 102 and adjacent the lid 154, and one or more lower sensor devices 195 disposed below the substrate 102 and adjacent the floor 152. The present disclosure contemplates that at least one of the one or more lower sensor devices 195 can be vertically aligned below at least one of the upper sensor devices 196, 196, 197 (such as outer sensor device 197).

Each sensor device 195, 196, 197, 198, can be a single-wavelength sensor device or a multi-wavelength (such as dual-wavelength) sensor device. In one or more embodiments, the system including the process chamber 100 includes any one, any two, or any three of the four illustrated sensor devices 195, 196, 197, 198. In one or more embodiments, the process chamber 100 includes one or more additional sensor devices, in addition to the sensor devices 195, 196, 197, 198. In one or more embodiments, the process chamber 100 may include sensor devices disposed at different locations and/or with different orientations than the illustrated sensor devices 195, 196, 197, 198.

As shown, a controller 190 is in communication with the processing chamber 100 and is used to control processes and methods, such as the operations of the methods described herein. The controller 190 is configured to receive data or input as sensor readings from sensor(s) (such as one or more of the sensor devices 195, 196, 197, 198). The sensor devices can include, for example: sensor devices that monitor growth of layer(s) on the substrate 102; and/or sensor devices that monitor temperatures of the substrate 102, the one or more heaters 200a, 200b, the one or more heaters 500a, 500b, the substrate support 106, and/or the liners 111, 163. As an example, one or more sensor devices 195, 196, 197, 198 can measure temperatures of the one or more heaters 200a, 200b and/or the one or more heaters 500a, 500b, and power to the one or more heaters 200a, 200b and/or the one or more heaters 500a, 500b can be controlled based on the measured temperatures (e.g., using a feedback control). As described the one or more sensor devices can include, for example pyrometers. In one or more embodiments, one or more thermocouples (e.g., proximity thermocouples) are disposed to measure temperatures of the one or more heaters 200a, 200b and/or the one or more heaters 500a, 500b, and power to the one or more heaters 200a, 200b and/or the one or more heaters 500a, 500b can be controlled based on the measured temperatures (e.g., using a feedback control).

The controller 190 includes a central processing unit (CPU) 193 (e.g., a processor), a memory 191 containing instructions, and support circuits 192 for the CPU 193. The controller 190 controls various items directly, or via other computers and/or controllers. In one or more embodiments, the controller 190 is communicatively coupled to dedicated controllers, and the controller 190 functions as a central controller.

The controller 190 is of any form of a general-purpose computer processor that is used in an industrial setting for controlling various substrate processing chambers and equipment, and sub-processors thereon or therein. The memory 191, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits 192 of the controller 190 are coupled to the CPU 193 for supporting the CPU 193. The support circuits 192 include cache, power supplies, clock circuits, input/output circuitry and subsystems, and the like. Operational parameters (e.g., a power supplied to the one or more heaters 200a, 200b and/or the one or more heaters 500a, 500b, a power applied to the heat sources 141, 143, a cleaning recipe, and/or a processing recipe) and operations are stored in the memory 191 as a software routine that is executed or invoked to turn the controller 190 into a specific purpose controller to control the operations of the various chambers/modules described herein. The controller 190 is configured to conduct any of the operations described herein. The instructions stored on the memory, when executed, cause one or more of the operations described herein to be conducted in relation to the processing chamber 100. The controller 190 and the processing chamber 100 are at least part of a system for processing substrates.

The various operations described herein can be conducted automatically using the controller 190, or can be conducted automatically or manually with certain operations conducted by a user.

The controller 190 is configured to control power to the one or more heaters 200a, 200b and/or the one or more heaters 500a, 500b, the deposition, the cleaning, the rotational position, the heating, and gas flow through the processing chamber 100 by providing an output to the controls for the sensor devices 195, 196, 197, 198, the one or more heaters 200a, 200b and/or the one or more heaters 500a, 500b, the upper heat sources 141, the lower heat sources 143, the process gas source 151, the purge gas source 162, the motion assembly 121, and/or the exhaust pump 157.

In one or more embodiments, the power supplied to the heaters 200a, 200b and/or the one or more heaters 500a, 500b includes alternating current (AC) within a range of 16 Amps to 64 Amps, such as 16 Amps to 32 Amps. In one or more embodiments, the power has a voltage that is 360 Volts or less. During processing, in one or more embodiments, the heaters 200a, 200b and/or the one or more heaters 500a, 500b are heated to a target heater temperature of 400 degrees Celsius or higher, such as 600 degrees Celsius or higher, for example within a range of 750 degrees Celsius to 850 degrees Celsius. During processing, in one or more embodiments, the substrate 102 is heated to a target temperature of 400 degrees Celsius or higher or 600 degrees Celsius or less. In one or more embodiments, the target temperature for the substrate 102 is within a range of 380 degrees Celsius to 600 degrees Celsius, for example 400 degrees Celsius to 500 degrees Celsius. In one or more embodiments, the target temperature for the substrate 102 is less than 500 degrees Celsius. In one or more embodiments, the target temperature for the substrate 102 is 400 degrees Celsius or less. In one or more embodiments, the target temperature for the substrate 102 is less than the target heater temperature.

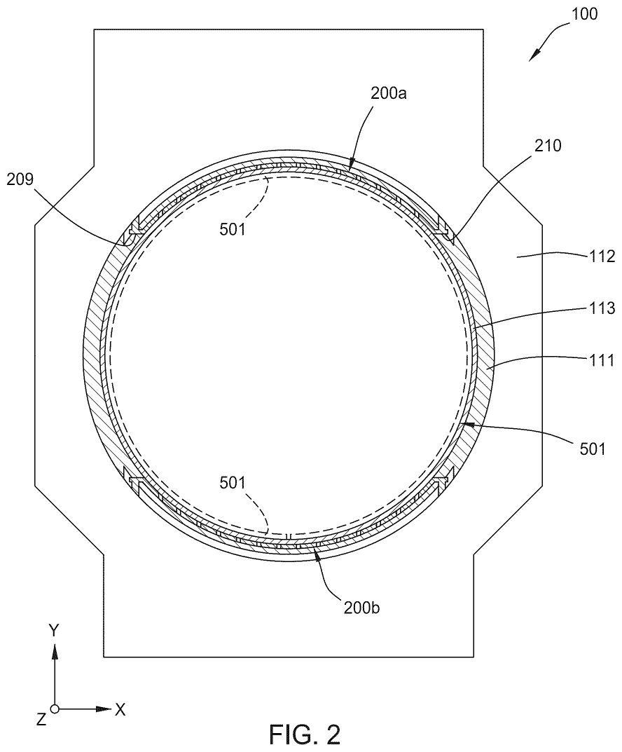

FIG. 2 is a schematic partial top cross-sectional view of the processing chamber 100 shown in FIG. 1, according to one or more embodiments. For visual clarity purposes, the flow module 112 and the pre-heat ring 501 are shown schematically and without hatching in FIG. 2.

In FIG. 2, the pre-heat ring 501 is shown in ghost as a single ring segment (e.g., a ring that includes a notch) for visual clarity purposes. The one or more heaters 500a, 500b shown in FIG. 1 are further described below in relation to FIGS. 5 and 6.

A first heater 200a is disposed adjacent to an inject side of the processing volume 136 and a second heater 200b is disposed adjacent to an exhaust side of the processing volume 136.

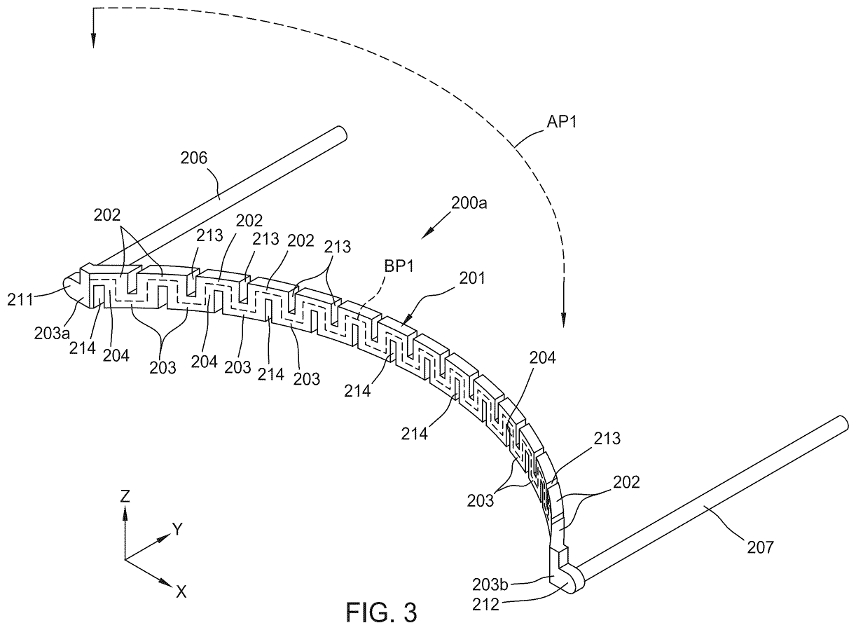

FIG. 3 is a schematic perspective view of the first heater 200a shown in FIGS. 1 and 2, according to one or more embodiments. The second heater 200b can include one or more aspects, features components, operations, and/or properties of the first heater 200a.

The first heater 200a includes an arcuate heater body 201 that includes one or more first sections 202 (a plurality is shown), one or more second sections 203 (a plurality is shown), and one or more connector sections 204 (a plurality is shown). The connector sections 204 respectively connect the first sections 202 to the second sections 203. The first heater 200a includes a first electrode 206 coupled to the arcuate heater body 201, and a second electrode 207 coupled to the arcuate heater body 201. Referring back to FIG. 1, the lower liner 111 includes a ledge 208 sized and shaped to at least partially support and/or cover the arcuate heater body 201. The first and second electrodes 206, 207 are shown in ghost for one heater 200b in FIG. 1 for visual clarity purposes. Referring back to FIG. 2, the lower liner 111 includes a first opening 209 sized and shaped to receive at least part of the first heater 200a therethrough, and a second opening 210 sized and shaped to receive at least part of the first heater 200a therethrough. In one or more embodiments, the first electrode 206 and/or the second electrode 207 have an outer diameter that is 20 mm or less. The present disclosure contemplates that the heater bodies described herein can have shapes other than arcuate shapes, such as rectangular shapes (e.g., semi-rectangular shapes), square shapes (e.g., semi-square shapes), zig-zag shapes (e.g., serpentine shapes), polygonal shapes (e.g., semi-polygonal shapes), angled shapes, and/or linear shapes. Other shapes are contemplated.

Referring again to FIG. 3, the first heater 200a includes a first flange section 211 coupled to the first electrode 206, and a second flange section 212 coupled to the second electrode 207. The one or more first sections 202 include a plurality of first sections 202 spaced from each other by a plurality of first openings 213, and the one or more second sections 203 include a plurality of second sections 203 spaced from each other by a plurality of second openings 214. The plurality of first openings 213 and the plurality of second openings 214 alternate with respect to each other along an arcuate length of the arcuate heater body 201.

The first electrode 206 and the second electrode 207 are coupled respectively to a pair of end second sections 203a, 203b of the plurality of second sections 203 through the first flange section 211 and the second flange section 212. The arcuate heater body 201 has a body profile BP1 including a plurality of reverse turns in an arcuate plane AP1 extending through at least some of the plurality of first sections 202 and the plurality of second sections 203. During heating of the heaters 200a, 200b, electrical current flows from the first electrode 206, through the arcuate heater body 201, and into the second electrode 207, which heats the arcuate heater body 201 in a resistive manner. Voltage can be generated across the arcuate heater body 201 and/or voltage can be supplied to the arcuate heater body 201.

In one or more embodiments, the arcuate heater body 201, the first electrode 206, and the second electrode 207 are formed of silicon carbide (SiC). In one or more embodiments, the arcuate heater body 201, the first electrode 206, and the second electrode 207 include a heating element (e.g., a metallic line, a wire (e.g., a metal wire, for example a copper wire), a metal mesh, and/or a metal rod) embedded in opaque quartz (e.g., white quartz, grey quartz, and/or black quartz) or transparent material (such as clear quartz). In one or more embodiments, the arcuate heater body 201, the first electrode 206, and the second electrode 207 are formed of graphite coated with SiC. The heating element can be wound about an inductor within the transparent material. As such, the heaters 200a, 200b can be resistive heaters, inductive heaters, and/or radiative heaters.

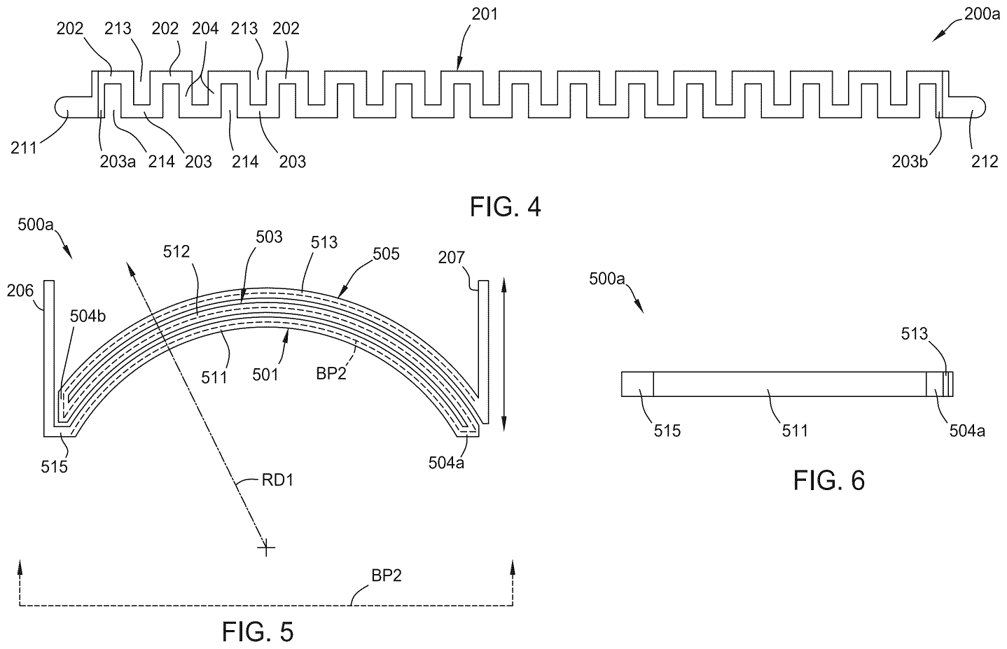

FIG. 4 is a schematic front view of the first heater 200a shown in FIG. 3, according to one or more embodiments.

FIG. 5 is a schematic partial top view of a first heater 500a of the one or more heaters 500a, 500b shown in FIG. 1, according to one or more embodiments. The first heater 500a includes one or more aspects, features components, operations, and/or properties of the first heater 200a shown in FIGS. 1-4. The second heater 500b can include one or more aspects, features components, operations, and/or properties of the first heater 500a.

The first heater 500a includes an arcuate heater body 501 that includes one or more first sections 502 (a single first section 502 is shown), one or more second sections 503 (a single second section 503 is shown), one or more third sections 505 (a single third section 505 is shown) and one or more connector sections 504a, 504b (a plurality is shown). The connector sections 504a, 504b respectively connect together the first section 502, the second section 503, and the third section 505. The one or more first sections 502 include a first ring segment 511, and the one or more second sections 503 include a second ring segment 512 spaced from the first ring segment 511 along a radial direction RD1. The one or more third sections 505 include a third ring segment 513 spaced from the second ring segment 512 along the radial direction RD1.

The one or more connector sections 504a, 504b include a first connector section 504a between an end of the first ring segment 511 and a first end of the second ring segment 512, and a second connector section 504b between a second end of the second ring segment 512 and an end of the third ring segment 513. A flange section 515 connected to the first ring segment 511 is coupled to the first electrode 206. The arcuate heater body 501 has a body profile BP2 including a plurality of reverse turns in a plane PL1 extending through the first ring segment 511, the second ring segment 512, and the third ring segment 513.

FIG. 6 is a schematic front view of the first heater 500a shown in FIG. 5, according to one or more embodiments.

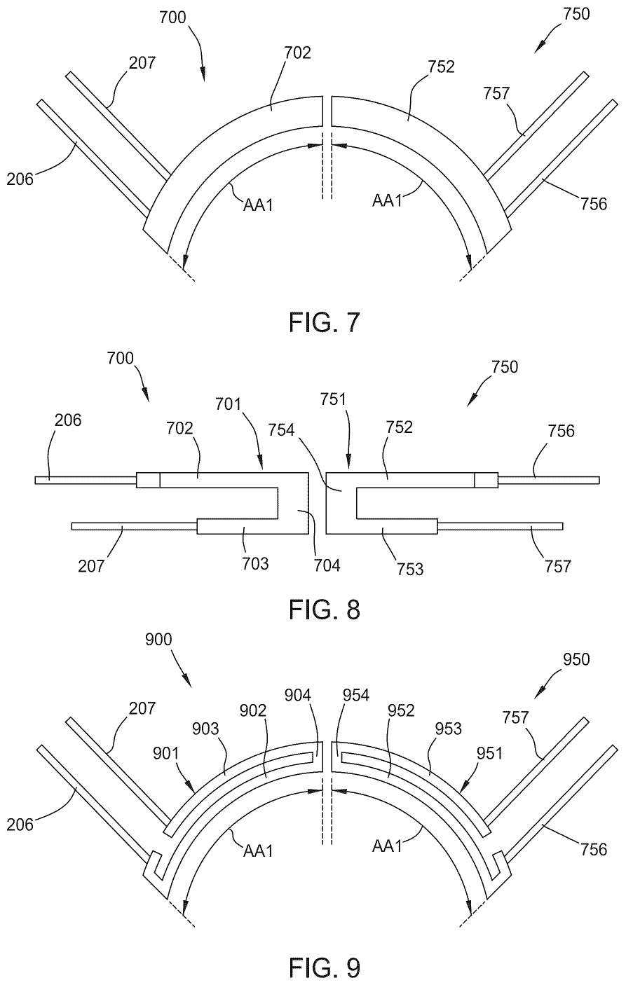

FIG. 7 is a schematic partial top view of a first heater 700 and a second heater 750, according to one or more embodiments.

FIG. 8 is a schematic front view of the first heater 700 and the second heater 750 shown in FIG. 7, according to one or more embodiments.

The first heater 700 and the second heater 750 can be disposed in place of the first heater 500a shown in FIG. 1. The first heater 700 and the second heater 750 include one or more aspects, features components, operations, and/or properties of the first heater 200a shown in FIGS. 1-4. Two heaters similar to the first heater 700 and the second heater 750 can be disposed on the exhaust side of the processing volume 136, in place of the second heater 500b shown in FIG. 1. The present disclosure contemplates that the heaters 700, 750 can have a different body profile. For example, in the top view shown in FIG. 7 and/or the front view shown in FIG. 8, the heaters 700, 750 can have the body profile BP1 shown in the front view in FIG. 4 and the perspective view shown in FIG. 3.

The first heater 700 includes a first heater body 701 that includes a first ring segment 702, a second ring segment 703 spaced from the first ring segment 702, and a connector section 704 between the first ring segment 702 and the second ring segment 703. The first heater 700 includes the first electrode 206 coupled to the first heater body 701, and the second electrode 207 coupled to the first heater body 701. In one or more embodiments, the ledge 208 of the lower liner 111 is sized and shaped to at least partially support and/or cover the first heater body 701 (such as the second ring segment 703 of the first heater body 701). The first ring segment 702 and the second ring segment 703 have an azimuthal angle AA1 between two ends, and the azimuthal angle AA1 is less than 90 degrees.

The second heater 750 includes a second heater body 751 including a third ring segment 752, a fourth ring segment 753 spaced from the third ring segment 752, and a second connector section 754 between the third ring segment 752 and the fourth ring segment 753. The second heater 750 includes a third electrode 756 coupled to the second heater body 751 and a fourth electrode 757 coupled to the second heater body 751.

FIG. 9 is a schematic partial top view of a first heater 900 and a second heater 950, according to one or more embodiments.

The first heater 900 and the second heater 950 can be disposed in place of the first heater 500a shown in FIG. 1. The first heater 900 and the second heater 950 include one or more aspects, features components, operations, and/or properties of the first heater 700 and the second heater 750 shown in FIGS. 7 and 8. Two heaters similar to the first heater 900 and the second heater 950 can be disposed on the exhaust side of the processing volume 136, in place of the second heater 500b shown in FIG. 1.

The first heater 900 includes a first heater body 901 that includes a first ring segment 902, a second ring segment 903 spaced from the first ring segment 902, and a connector section 904 between the first ring segment 902 and the second ring segment 903. The first heater 900 includes the first electrode 206 coupled to the first heater body 901, and the second electrode 207 coupled to the first heater body 901. In one or more embodiments, the ledge 208 of the lower liner 111 is sized and shaped to at least partially support and/or cover the first heater body 901 (such as the second ring segment 903 of the first heater body 901).

The second heater 950 includes a second heater body 751 including a third ring segment 952, a fourth ring segment 953 spaced from the third ring segment 952, and a second connector section 954 between the third ring segment 952 and the fourth ring segment 953. The second heater 950 includes the third electrode 756 coupled to the second heater body 951 and the fourth electrode 757 coupled to the second heater body 951. The present disclosure contemplates that the heaters 900, 950 can have a different body profile. For example, in the top view shown in FIG. 9 the heaters 900, 950 can have the body profile BP1 shown in the front view in FIG. 4 and the perspective view shown in FIG. 3.

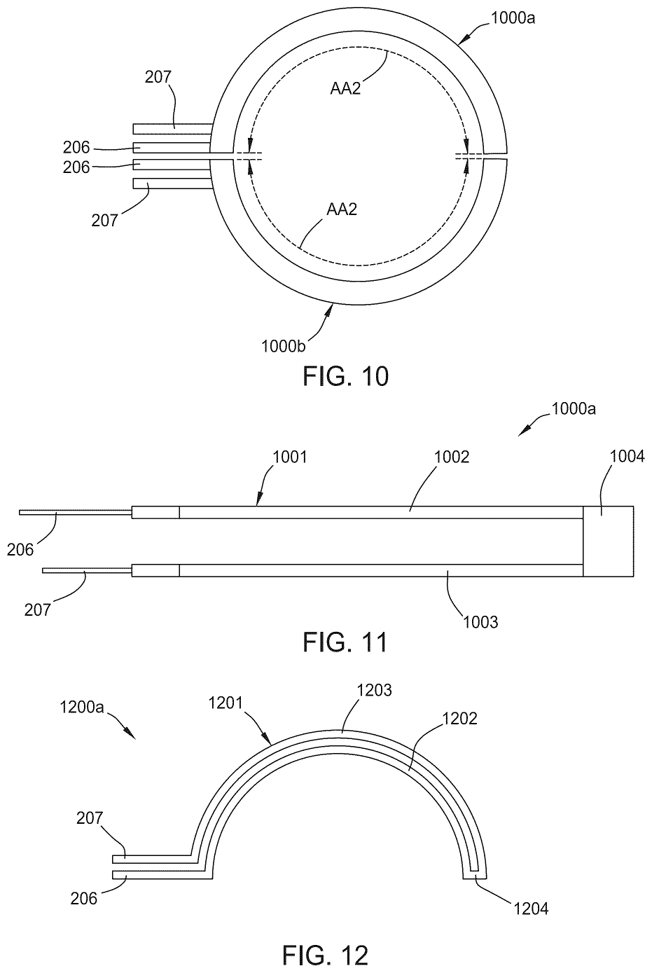

FIG. 10 is a schematic partial top view of a first heater 1000a and a second heater 1000b, according to one or more embodiments.

FIG. 11 is a schematic front view of the first heater 1000a shown in FIG. 10, according to one or more embodiments.

The first heater 1000a and the second heater 1000b can be disposed in place of the first heater 500a and the second heater 500b shown in FIG. 1. The first heater 1000a and the second heater 1000b include one or more aspects, features components, operations, and/or properties of the first heater 200a shown in FIGS. 1-4. The second heater 1000b can include one or more aspects, features components, operations, and/or properties of the first heater 1000a. The first heater 1000a and the second heater 1000b can be used in place of the first heater 500a and the second heater 500b shown in FIG. 1.

The first heater 1000a includes a first heater body 1001 that includes a first ring segment 1002, a second ring segment 1003 spaced from the first ring segment 1002, and a connector section 1004 between the first ring segment 1002 and the second ring segment 1003. The first heater 1000a includes the first electrode 206 coupled to the first heater body 1001, and the second electrode 207 coupled to the first heater body 1001. In one or more embodiments, the ledge 208 of the lower liner 111 is sized and shaped to at least partially support and/or cover the first heater body 701 (such as the second ring segment 1003 of the first heater body 1001). The first ring segment 1002 and the second ring segment 1003 have an azimuthal angle AA2 between two ends, and the azimuthal angle AA2 is within a range of 90 degrees to 180 degrees. The present disclosure contemplates that the heaters 1000a, 1000b can have a different body profile. For example, in the top view shown in FIG. 10 and/or the front view shown in FIG. 11, the heaters 1000a, 1000b can have the body profile BP2 shown in the top view in FIG. 5.

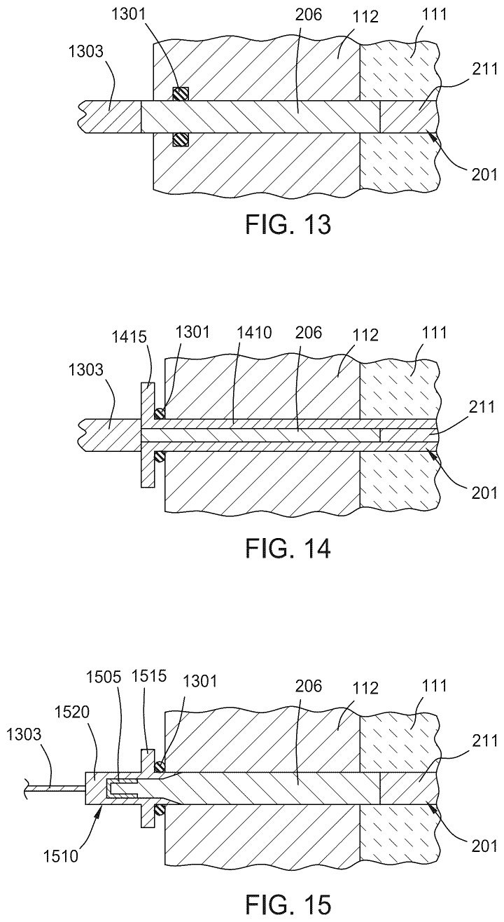

FIG. 12 is a schematic partial top view of a first heater 1200a, according to one or more embodiments. A second heater 1200b can include one or more aspects, features components, operations, and/or properties of the first heater 1200a.

The first heater 1200a and the second heater 1200b can be disposed in place of the first heater 500a and the second heater 500b shown in FIG. 1. The first heater 1200a and the second heater 1200b include one or more aspects, features components, operations, and/or properties of the first heater 1000a and the second heater 1000b shown in FIGS. 10 and 11.

The first heater 1200a includes a first heater body 1201 that includes a first ring segment 1202, a second ring segment 1203 spaced from the first ring segment 1202, and a connector section 1204 between the first ring segment 1202 and the second ring segment 1203. The first heater 1200a includes the first electrode 206 coupled to the first heater body 1201, and the second electrode 207 coupled to the first heater body 1201. In one or more embodiments, the ledge 208 of the lower liner 111 is sized and shaped to support the first heater body 901 (such as the second ring segment 1203 of the first heater body 1201).

FIG. 13 is a schematic partial cross-sectional side view of the first heater 200a shown in FIG. 3 disposed in the processing chamber 100 in FIG. 1, according to one or more embodiments.

As shown for the first electrode 206 in FIG. 13, the first electrode 206 and the second electrode 207 both extend at least partially through the chamber body (such as the flow module 112). In one or more embodiments, the first and second electrodes 206, 207 extend through the chamber body and to an exterior side of the chamber body that is atmospheric. A seal 1301 is disposed about each of the first electrode 206 and the second electrode 207 to fluidly isolate the atmospheric exterior side from a vacuum side of the chamber body. In one or more embodiments, the first and second electrodes 206, 207 are formed of the same material as the arcuate heater body 201. In one or more embodiments, the first and second electrodes 206, 207 are formed of SiC. An electrical line 1303 is respectively connected to the first electrode 206 and the second electrode 207. As described above, the first electrode 206 and the second electrode 207 are coupled (e.g., bonded) to the arcuate heater body 201.

FIG. 14 is a schematic partial cross-sectional side view of the first heater 200a shown in FIG. 3 disposed in the processing chamber 100 in FIG. 1, according to one or more embodiments.

As shown for the first electrode 206 in FIG. 14, a quartz sleeve 1410 is disposed respectively about each of the first electrode 206 and the second electrode 207. In one or more embodiments, the quartz sleeve 1410 is formed of a transparent quartz or opaque quartz. In one or more embodiments, the arcuate heater body 201 is embedded in the same quartz material as the quartz sleeve 1410. In one or more embodiments, the quartz sleeve 1410 is coupled (e.g., bonded) to the arcuate heater body 201 and/or the first electrode 206. The seal 1301 can be disposed between the chamber body (e.g., the flow module 112) and a shoulder 1415 of the quartz sleeve 1410. The shoulder 1415 can abut against the chamber body.

FIG. 15 is a schematic partial cross-sectional side view of the first heater 200a shown in FIG. 3 disposed in the processing chamber 100 in FIG. 1, according to one or more embodiments.

As shown for the first electrode 206 in FIG. 15, the first electrode 206 and the second electrode 207 are received in a respective electrical socket 1505 of a hermetic feedthrough assembly 1510. The seal 1301 can be disposed between the chamber body (e.g., the flow module 112) and a shoulder 1515 of a socket housing 1520. The shoulder 1515 can abut against the chamber body.

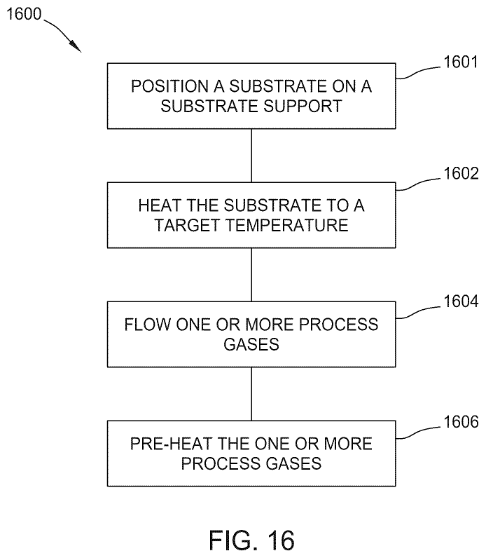

FIG. 16 is a schematic block diagram view of a method 1600 of substrate processing for semiconductor manufacturing, according to one or more embodiments.

Operation 1601 includes positioning a substrate on a substrate support in a processing volume of a processing chamber. In one or more embodiments, the positioning includes moving a substrate support and/or a plurality of lift pins relative to each other to land the substrate on the substrate support.

Operation 1602 of the method 1600 includes heating the substrate to a target temperature. In one or more embodiments, the target temperature is less than 500 degrees Celsius. In one or more embodiments, the target temperature is 400 degrees Celsius or less.

Operation 1604 includes flowing one or more process gases.

Operation 1606 includes pre-heating the one or more process gases. The one or more process gases flow over one or more of the heaters described herein, which pre-heats the one or more process gases and pre-activates the one or more process gases. The one or more process gases then flow over the substrate to form one or more layers on the substrate.

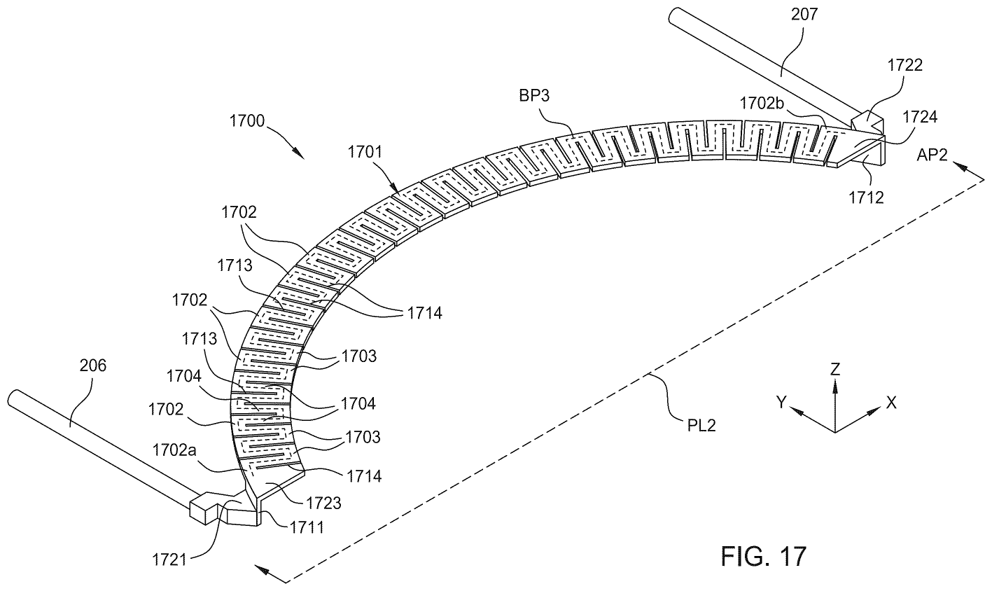

FIG. 17 is a schematic perspective view of a heater 1700, according to one or more embodiments. The heater 1700 can include one or more aspects, features components, operations, and/or properties of the first heater 200a and/or the first heater 500a. The heater 1700 can be used in place of the first heater 200a, the second heater 200b, the first heater 500a, and/or the second heater 500b.

The heater 1700 includes an arcuate heater body 1701 that includes one or more first sections 1702 (a plurality is shown), one or more second sections 1703 (a plurality is shown), and one or more connector sections 1704 (a plurality is shown). The connector sections 1704 respectively connect the first sections 1702 to the second sections 1703. The heater 1700 includes the first electrode 206 coupled to the arcuate heater body 1701, and the second electrode 207 coupled to the arcuate heater body 1701.

The first heater 200a includes a first flange section 1711 coupled to the first electrode 206 through a first extension section 1721, and a second flange section 1712 coupled to the second electrode 207 through a second extension section 1722. The one or more first sections 1702 include a plurality of first sections 1702 spaced from each other by a plurality of first openings 1713, and the one or more second sections 1703 include a plurality of second sections 1703 spaced from each other by a plurality of second openings 1714. The plurality of first openings 1713 and the plurality of second openings 1714 alternate with respect to each other along an arcuate length of the arcuate heater body 1701.

The first flange section 1711 and the second flange section 1712 are coupled respectively to a pair of end sections 1723, 1724 of the arcuate heater body 1701. In one or more embodiments, the end sections 1723, 1724 respectively have a radial width that span the first section 1702, the second sections 1703, and the connector sections 1704. The arcuate heater body 1701 has a body profile BP3 including a plurality of reverse turns in a plane PL2 (e.g., a horizontal plane, such as the X-Y plane) extending through at least some of the plurality of first sections 1702 and the plurality of second sections 1703. In one or more embodiments, the plane PL2 extends through the first sections 1702, the second sections 1703, the connector sections 1704, and the end sections 1723, 1724. During heating of the heater 1700, electrical current flows from the first electrode 206, through the arcuate heater body 1701, and into the second electrode 207, which heats the arcuate heater body 1701 in a resistive manner. Voltage can be generated across the arcuate heater body 701 and/or voltage can be supplied to the arcuate heater body 701.

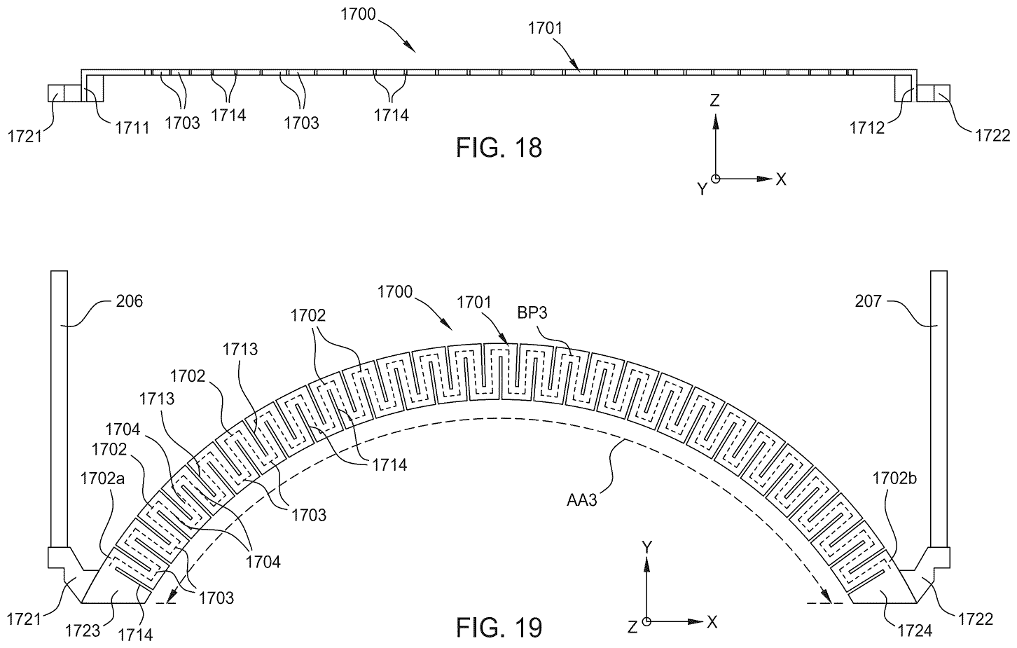

In one or more embodiments, the arcuate heater body 1701, the first electrode 206, and the second electrode 207 are formed of silicon carbide (SiC). In one or more embodiments, the arcuate heater body 1701, the first electrode 206, and the second electrode 207 include a heating element (e.g., a metallic line, a wire (e.g., a metal wire, for example a copper wire), a metal mesh, and/or a metal rod) embedded in formed of opaque quartz (e.g., white quartz, grey quartz, and/or black quartz) or a transparent material (such as clear quartz). In one or more embodiments, the arcuate heater body 1701, the first electrode 206, and the second electrode 207 are formed of graphite coated with SiC. The heating element can be wound about an inductor within the transparent material. As such, the heater 1700 can be a resistive heater, inductive heater, and/or radiative heater. FIG. 18 is a schematic front view of the heater 1700 shown in FIG. 17, according to one or more embodiments.

FIG. 19 is a schematic top view of the heater 1700 shown in FIGS. 17 and 18, according to one or more embodiments.

The connector sections 1704 extend radially along a radial direction RD2. The first sections 1702 and the second sections 1703 extend azimuthally relative to the radial direction RD2.

The connector sections 504a, 504b respectively connect together the first section 502, the second section 503, and the third section 505. The one or more first sections 502 include a first ring segment 511, and the one or more second sections 503 include a second ring segment 512 spaced from the first ring segment 511 along a radial direction RD1. The one or more third sections 505 include a third ring segment 513 spaced from the second ring segment 512 along the radial direction RD1.

The arcuate heater body 1701 has an azimuthal angle AA2 between two ends (such as outer ends of the end sections 1723, 1724), and the azimuthal angle AA3 is within a range of 90 degrees to 180 degrees. In one or more embodiments, the azimuthal angle AA3 is greater than 90 degrees (such as greater than 120 degrees) and less than 180 degrees.

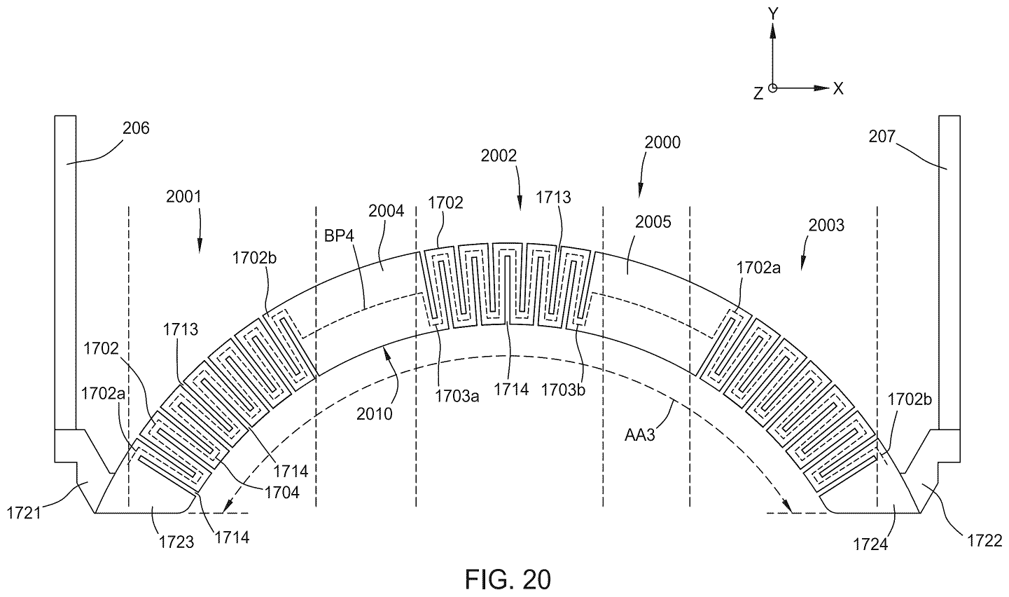

FIG. 20 is a schematic perspective top of a heater 2000, according to one or more embodiments. The heater 2000 can include one or more aspects, features components, operations, and/or properties of the first heater 200a and/or the first heater 500a. The heater 2000 can be used in place of the first heater 200a, the second heater 200b, the first heater 500a, and/or the second heater 500b.

The heater 2000 is similar to the heater 1700 shown in FIGS. 17-19, and includes one or more aspects, features, components, properties, and/or operations thereof. The respective first sections 1702, the respective second sections 1703, the respective first openings 1713, and the respective second openings 1714 are grouped into a plurality of sets 2001-2003 (three sets are shown). A first set 2001 and a third set 2003 include a pair of end first sections 1702a, 1702b, and a second set 2002 includes a pair of end second sections 1703a, 1703b.

An arcuate heater body 2010 of the heater 2000 has a body profile BP4 including a plurality of reverse turns in the plane PL2 (e.g., a horizontal plane, such as the X-Y plane) extending through at least some of the plurality of first sections 1702 and the plurality of second sections 1703. The reverse turns are grouped into the plurality of sets 2001-2003. The body profile BP4 includes arcuate sections azimuthally between the sets 2001-2003. The arcuate heater body 2010 includes solid sections 2004, 2005 (e.g., arcuate solid sections) azimuthally between the sets 2001-2003 of sections 1702, 1703. The solid sections 2004, 2005 can have for example a solid cross section (such as a solid rectangular cross section). The solid sections 2004, 2005 can omit the first and second openings 1713, 1714. In one or more embodiments, the first and third groups 2001, 2033 are aligned with outer heating zones and the second group 2002 is aligned with an inner heating zone. In one or more embodiments, the solid sections 2004, 2005 are aligned with intermediate heating zones between the inner heating zone and the outer heating zones. The heating zones can correspond to processing zones of a substrate being processed. In one or more embodiments, the sets 2001-2003 involve heating zones that heat to a higher temperature than heating zones of the solid sections 2004, 2005. For example, gas(es) involving a higher activation temperature can flow over the zones of the sets 2001-2003, and gas(es) involving a lower activation temperature can flow over the zones of the solid sections 2004, 2005. The present disclosure contemplates that a lower number of reverse turns can be used for lower activation temperatures, and a larger number of reverse turns can be used for higher activation temperatures.

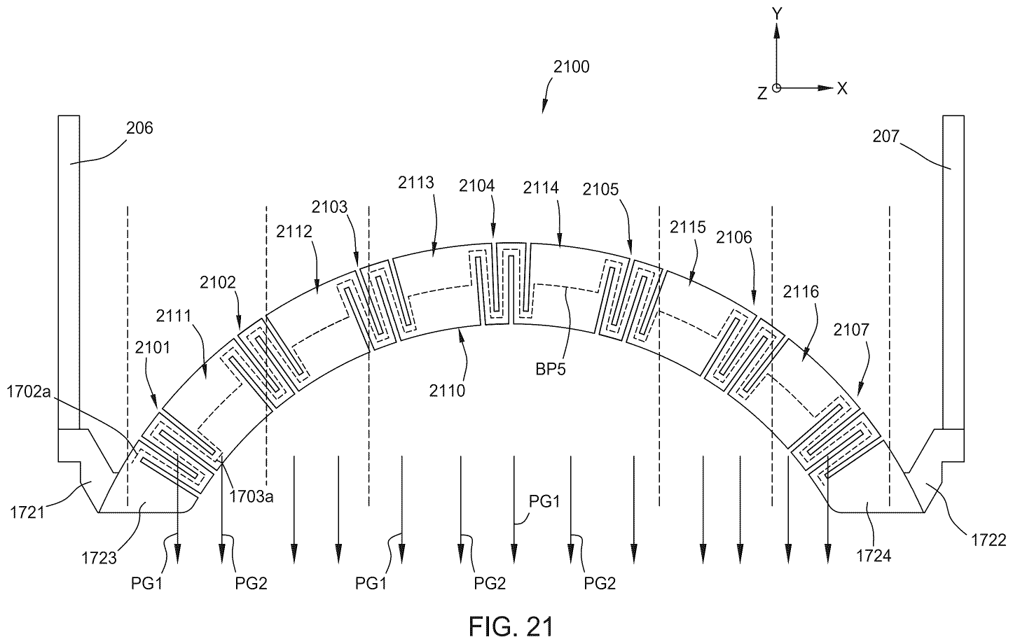

The present disclosure contemplates that multiple gases involving multiple activation temperatures can flow into respective heating zones (see for example FIG. 21). FIG. 20 shows three sets 2001-2003 corresponding to three higher heating zones and two solid sections 2004, 2005 corresponding to two lower heating zones. The present disclosure contemplates that a different (e.g., higher or lower) number of sets and higher heating zones may be used, and/or a different (e.g., higher or lower) number of solid sections and lower heating zones may be used.

FIG. 21 is a schematic perspective top of a heater 2100, according to one or more embodiments. The heater 2100 can include one or more aspects, features components, operations, and/or properties of the first heater 200a and/or the first heater 500a. The heater 2100 can be used in place of the first heater 200a, the second heater 200b, the first heater 500a, and/or the second heater 500b.

The heater 2100 is similar to the heater 2000 shown in FIG. 20, and includes one or more aspects, features, components, properties, and/or operations thereof. The respective first sections 1702, the respective second sections 1703, the respective first openings 1713, and the respective second openings 1714 are grouped into a plurality of sets 2101-2107 (seven sets are shown). The seven sets 2101-2107 respectively include an end first section 1702a and an end second section 1703a.

An arcuate heater body 2110 of the heater 2100 has a body profile BP5 including a plurality of reverse turns in the plane PL2. The reverse turns are grouped into the plurality of sets 2101-2107. The body profile BP5 includes arcuate sections azimuthally between the sets 2101-2107. The arcuate heater body 2110 includes solid sections 2111-2116 (e.g., arcuate solid sections) azimuthally between the sets 2101-2107 of sections 1702, 1703. The solid sections 2111-2116 can have for example a solid cross section (such as a solid rectangular cross section). In one or more embodiments, the first and seventh sets 2101, 2107 are aligned with outer heating zones and the fourth set 2104 is aligned with an inner heating zone. In one or more embodiments, the first solid section 2111 and the sixth solid section 2116 are aligned with outer heating zones, and the third and fourth solid sections 2113, 2114 are aligned with the inner heating zones. In one or more embodiments, the second and fifth solid sections 2112, 2115 are aligned with intermediate heating zones. Sets and/or solid sections (such as the second set 2102, the third set 2103 shown in FIG. 21) can partially overlap with multiple heating zones. Two or more process gases PG1, PG2 involving two or more activation temperatures flow respectively in the heating zones.

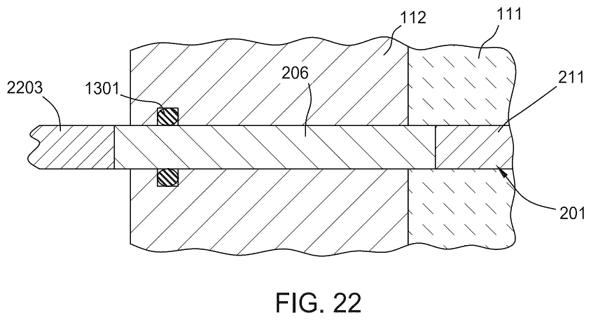

FIG. 22 is a schematic partial cross-sectional side view of the first heater 200a shown in FIG. 3 disposed in the processing chamber 100 in FIG. 1, according to one or more embodiments. The implementation shown in FIG. 22 is similar to the implementation shown in FIG. 13, and includes one or more aspects, features components, operations, and/or properties thereof. FIG. 22 shows a metal-to-SiC hybrid electrode.

The present disclosure contemplates that the seal 1301 can be omitted. Metallic lines 2203 are connected to the first and second electrodes 206, 207. The metallic lines 2203 are formed of a metallic material (such as copper and/or aluminum), the first and second electrodes 206, 207 are formed of SiC, and the first and second flange sections 211, 212 are formed of SiC. A variety of metallic materials are contemplated for the metallic lines 2203. In one or more embodiments, the metallic material has a coefficient of thermal expansion that is within a difference of 50% or less relative to a coefficient of thermal expansion of the SiC of the first and second electrodes 206, 207. In one or more embodiments, the first and second electrodes 206, 207 are bonded to the arcuate heater body 201, and the electrical lines 2203 are brazed to the first and second electrodes 206, 207.

Benefits of the present disclosure include reliable gas activation; adjustability of gas activation; modularity in chamber application; more uniform gas activation; temperature uniformity (e.g., temperature uniformity in an outer region of the substrate); reduced gas consumption and gas waste; increased growth rates; and more uniform film growth and/or dopant concentration. Benefits also include enhanced heater ductility; enhanced thermal shock resistance for heaters; and increased heating rates for heaters (e.g., 4-5 degrees Celsius or higher).

Benefits further include enhanced device performance; efficient processing; and increased throughput. As an example, the gas activation is facilitated for substrate target temperatures less than 500 degrees Celsius, such as target temperatures within a range of 380 degrees to 500 degrees Celsius. For example, the gas can be activated to about 500 degrees Celsius or higher over the substrate when the substrate is at about 400 degrees Celsius.

It is contemplated that one or more aspects disclosed herein may be combined. As an example, one or more aspects, features, components, operations and/or properties of the processing chamber 100; the controller 190; the one or more sensor devices 195, 196, 197, 198; the heater(s) 200a, 200b; the pre-heat ring 501; the heater(s) 500a, 500b; the heater(s) 700, 750; the heater(s) 900, 950; the heater(s) 1000a, 1000b; the heater(s) 1200a, 1200b; the seal 1301; the quartz sleeve 1410; the hermetic feedthrough assembly 1510; the heater(s) 1700, the heater(s) 2000, and/or the heater(s) 2100 may be combined. Moreover, it is contemplated that one or more aspects disclosed herein may include some or all of the aforementioned benefits.

The present disclosure contemplates that in any of the heater arrangements herein, the electrodes 206, 207 can be disposed in the same plane (e.g., the same elevation) as shown for example in FIGS. 3, 4, and 18, or can be disposed in different planes (e.g., a top plane and a bottom plane) as shown for example in FIGS. 8 and 11.

While the foregoing is directed to embodiments of the present disclosure, other and further embodiments of the disclosure may be devised without departing from the basic scope thereof, and the scope thereof is determined by the claims that follow.

What is claimed is:

1. A chamber kit applicable for semiconductor manufacturing, comprising:
a heater comprising:
a heater body comprising one or more first sections, one or more second sections, and one or more connector sections,
a first electrode coupled to the heater body, and
a second electrode coupled to the heater body; and
a liner comprising:
a ledge sized and shaped to support the heater body,
a first opening sized and shaped to receive at least part of the heater therethrough, and
a second opening sized and shaped to receive at least part of the heater therethrough.

2. The chamber kit of claim 1, wherein the one or more first sections comprise a plurality of first sections spaced from each other by a plurality of first openings, and the one or more second sections comprise a plurality of second sections spaced from each other by a plurality of second openings.

3. The chamber kit of claim 2, wherein the plurality of first openings and the plurality of second openings alternate with respect to each other along a length of the heater body, the first sections and the second sections are grouped into a plurality of sets, and the heater body further comprises one or more solid sections azimuthally between the plurality of sets.

4. The chamber kit of claim 2, wherein the first electrode and the second electrode are coupled respectively to a first flange section and a second flange section of the heater.

5. The chamber kit of claim 2, wherein the heater body has a body profile including a plurality of reverse turns in a plane extending through at least some of the plurality of first sections and the plurality of second sections.

6. The chamber kit of claim 1, wherein the one or more first sections comprise a first ring segment, and the one or more second sections comprise a second ring segment spaced from the first ring segment along a radial direction.

7. The chamber kit of claim 6, wherein the heater body further comprises a third ring segment spaced from the second ring segment along the radial direction.

8. The chamber kit of claim 7, wherein the one or more connector sections comprise:
a first connector section between an end of the first ring segment and a first end of the second ring segment; and
a second connector section between a second end of the second ring segment and an end of the third ring segment.

9. The chamber kit of claim 7, wherein the heater body has a body profile including a plurality of reverse turns in a plane extending through the first ring segment, the second ring segment, and the third ring segment.

10. The chamber kit of claim 1, wherein the heater body, the first electrode, and the second electrode are formed of silicon carbide (SiC).

11. The chamber kit of claim 1, wherein the heater body is formed of opaque quartz, and the first electrode and the second electrode each comprise a heating element embedded in the opaque quartz.

12. A chamber kit applicable for semiconductor manufacturing, comprising:
a heater comprising:
a heater body comprising a first ring segment, a second ring segment spaced from the first ring segment, and a connector section between the first ring segment and the second ring segment,
a first electrode coupled to the heater body, and
a second electrode coupled to the heater body; and
a liner comprising a ledge sized and shaped to support the heater body.

13. The chamber kit of claim 12, wherein the first ring segment and the second ring segment have an azimuthal angle between two ends, and the azimuthal angle is less than 90 degrees.

14. The chamber kit of claim 12, wherein the first ring segment and the second ring segment have an azimuthal angle between two ends, and the azimuthal angle is within a range of 90 degrees to 180 degrees.

15. The chamber kit of claim 12, further comprising a second heater comprising:
a second heater body comprising a third ring segment, a fourth ring segment spaced from the third ring segment, and a second connector section between the third ring segment and the fourth ring segment;
a third electrode coupled to the second heater body; and
a fourth electrode coupled to the second heater body.

16. A processing chamber applicable for use in semiconductor manufacturing, comprising:
a chamber body comprising an inject side and an exhaust side;
a substrate support disposed in a processing volume; and
a heater disposed adjacent the inject side of the chamber body, the heater comprising:
an arcuate heater body comprising one or more first sections, one or more second sections, and one or more connector sections,
a first electrode coupled to the arcuate heater body and extending at least partially through the chamber body, and
a second electrode coupled to the arcuate heater body and extending at least partially through the chamber body.

17. The processing chamber of claim 16, further comprising a seal disposed about each of the first electrode and the second electrode.

18. The processing chamber of claim 16, further comprising a quartz sleeve disposed respectively about each of the first electrode and the second electrode.

19. The processing chamber of claim 16, wherein the first electrode and the second electrode are received in a respective electrical socket of a hermetic feedthrough assembly.

20. The processing chamber of claim 16, further comprising a second heater disposed adjacent the exhaust side of the chamber body, the second heater comprising:
a second arcuate heater body comprising one or more third sections, one or more fourth sections, and one or more second connector sections;
a third electrode coupled to the arcuate heater body; and
a fourth electrode coupled to the arcuate heater body.
